(19) United States
(12) Patent Application Publication
(10) Pub. No.: US 2015/0014569 A1
(43) Pub. Date: Jan. 15, 2015

(54) COATING ARRANGEMENT FOR SLIDING ACTUATOR ASSEMBLY AND METHOD

(71) Applicant: Hamilton Sundstrand Corporation, Charlotte, NC (US)

(72) Inventors: Kevin M. Rankin, Windsor, CT (US); Peter M. Ballard, Enfield, CT (US)

(73) Assignee: Hamilton Sundstrand Corporation, Charlotte, NC (US)

(21) Appl. No.: 14/193,145

(22) Filed: Feb. 28, 2014

Related U.S. Application Data
(60) Provisional application No. 61/844,599, filed on Jul. 10, 2013.

(51) Int. Cl. F16K 27/04; C23C 14/06

(52) U.S. Cl. CPC F16K 27/041; C23C 14/0611
USPC 251/366; 427/299; 427/249.7

(57) ABSTRACT

A coated valve assembly includes a sleeve having a sleeve outer surface and a sleeve inner surface. Also included is a spool having a spool outer surface. Further included is a hardened surface formed on the sleeve inner surface and the spool outer surface. Yet further included is a coating disposed on the hardened surface of at least one of the spool outer surface and the sleeve inner surface, the second coating comprising a diamond-like carbon coating.

### CROSS-REFERENCE TO RELATED APPLICATIONS

This patent application claims priority to U.S. Provisional Application No. 61/844,599, filed Jul. 10, 2013, which is incorporated herein by reference in its entirety.

### BACKGROUND OF THE INVENTION

The present invention relates to sliding actuator assemblies, and more particularly to coating arrangements for various components of sliding actuator assemblies, as well as a method of coating such components.

Various sliding applications, such as valve assemblies, for example, employ a spool-in-sleeve configuration. These applications are often manufactured from hardened steel primarily for wear resistance. Significant weight savings could be realized by constructing spool and sleeve components from non-steel materials. Valve assemblies, such as metering valves and pressure regulating valves, experience small-amplitude dither motion throughout their normal operation which leads to more aggressive wear, thereby typically necessitating self-mated steel configurations. Coatings applied directly on softer, non-steel materials often experience a failure mode in which local high contact stress causes deformation of soft substrates since the coating is very thin.

### BRIEF DESCRIPTION OF THE INVENTION

According to one embodiment, a coated valve assembly includes a sleeve having a sleeve outer surface and a sleeve inner surface. Also included is a spool having a spool outer surface. Further included is a hardened surface formed on the sleeve inner surface and the spool outer surface. Yet further included is a coating disposed on the hardened surface of at least one of the spool outer surface and the sleeve inner surface, the second coating comprising a diamond-like carbon coating.

According to another embodiment, a method of coating components of a valve assembly is provided. The method includes hardening a spool outer surface of a spool to form a spool hardened surface having a surface roughness of about 0.000004 inches. The method also includes hardening a sleeve inner surface of a sleeve to form a sleeve hardened surface having a surface roughness of about 0.000004 inches. The method further includes applying a diamond-like carbon coating on the hardened surface of at least one of the spool outer surface and the sleeve inner surface.

According to yet another embodiment, a coating arrangement for sliding actuator assembly includes a first component having an outer surface and an inner surface. Also included is a second component having an outer surface. Further included is a hardened surface formed on the inner surface of the first component and the outer surface of the second component. Yet further included is a coating disposed on the hardened surface of at least one of the outer surface of the second component and the inner surface of the first component, the second coating comprising a diamond-like carbon coating.

### BRIEF DESCRIPTION OF THE DRAWINGS

The subject matter which is regarded as the invention is particularly pointed out and distinctly claimed in the claims at the conclusion of the specification. The foregoing and other features and advantages of the invention are apparent from the following detailed description taken in conjunction with the accompanying drawings in which:

FIG. 1 is a sectional illustration of a first type of valve assembly;

FIG. 2 is a perspective view of a spool of the first type of valve assembly of FIG. 1;

FIG. 3 is a perspective view of a sleeve of the first type of valve assembly of FIG. 1;

FIG. 4 is a sectional illustration of a second type of valve assembly;

FIG. 5 is a perspective view of a sleeve of the second type of valve assembly of FIG. 4;

FIG. 6 is a perspective view of a spool of the second type of valve assembly of FIG. 4;

FIG. 7 is a cross-sectional view of a coating arrangement according to a first embodiment;

FIG. 8 is a cross-sectional view of the coating arrangement according to a second embodiment;

FIG. 9 is a cross-sectional view of the coating arrangement according to a third embodiment; and

FIG. 10 is a flow diagram illustrating a method of coating components of a valve assembly.

### DETAILED DESCRIPTION OF THE INVENTION

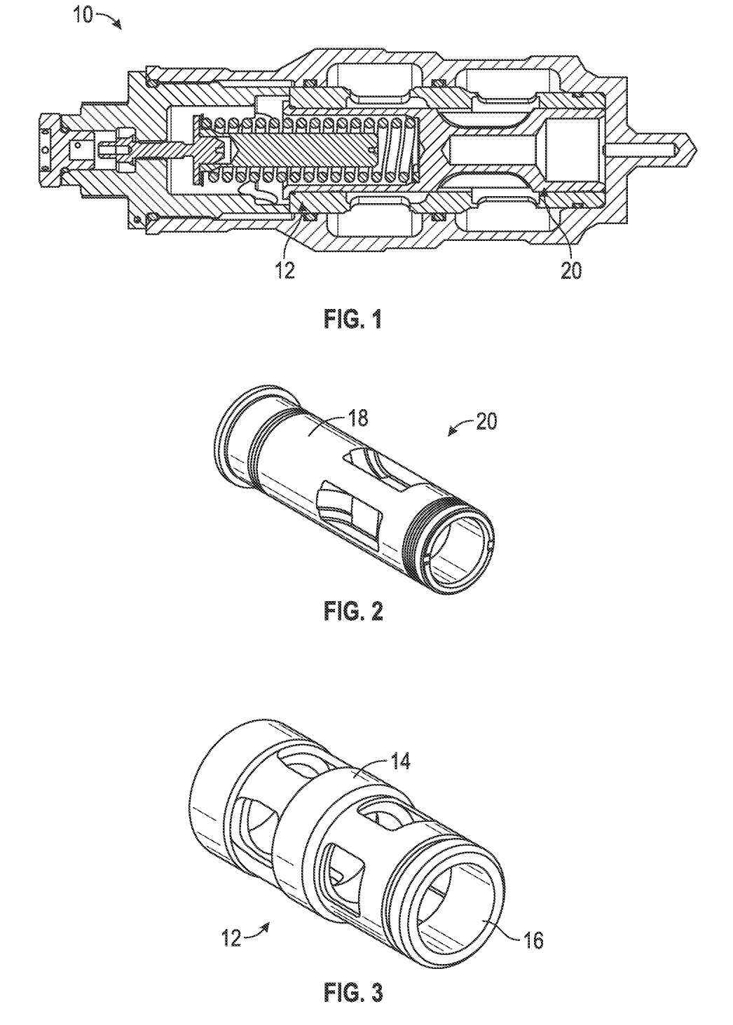

Referring to FIG. 1, a section of a valve assembly 10 is shown. The valve assembly 10 illustrated in FIG. 1 comprises a first type of valve assembly, while a second type of valve assembly is illustrated in FIG. 4. The first type of valve assembly is a pressure regulating valve and the second type is a metering valve, such as a fuel control metering valve. The valve assemblies illustrated are merely exemplary embodiments of the valve assembly 10 and it is to be appreciated that any type of valve assembly may benefit from the embodiments described herein. Furthermore, it is contemplated that any sliding application having components with relative sliding motion between the components may be employed, particularly those with lightly-loaded applications having conformal contact surfaces with geometry that prevents high contact stress (e.g., from edge loading), and where low-friction and resistance to sliding and fretting wear are desirable.

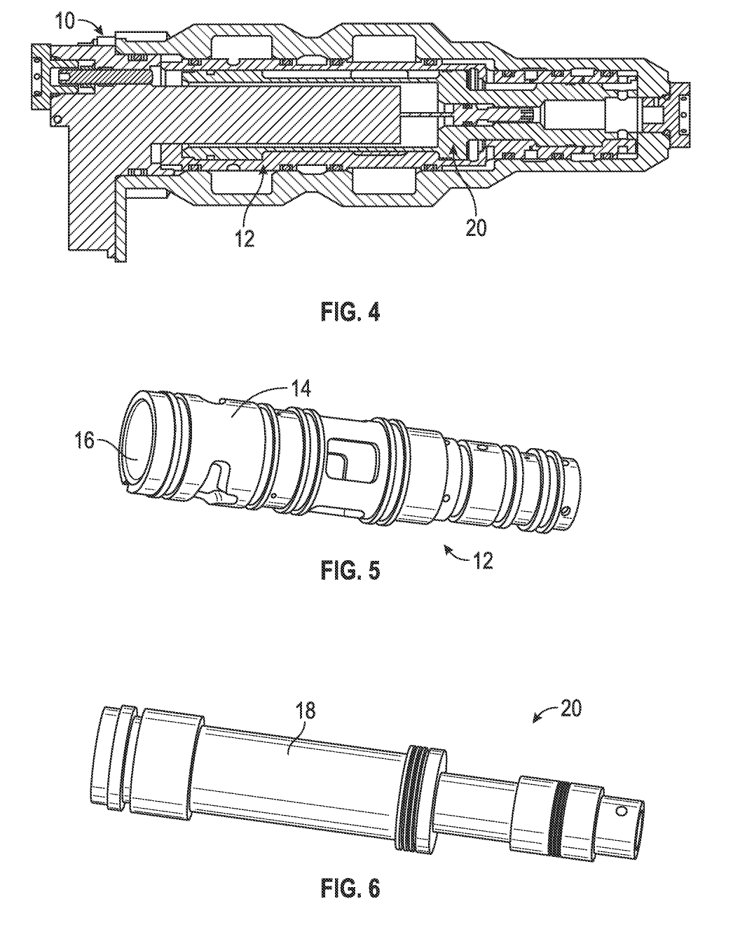

Referring now to FIGS. 1-6, the valve assembly 10 according to the two embodiments described above is shown with FIGS. 2, 3, 5 and 6 showing individual components of the valve assembly 10. Specifically, the valve assembly 10 includes a sleeve 12 having a sleeve outer surface 14 and a sleeve inner surface 16. The geometry of the sleeve inner surface 16 may vary, but generally corresponds to a spool outer surface 18 of a spool 20 configured to be at least partially disposed within the sleeve 12. The sleeve 12 and the spool 20 are arranged to slide relative to each other during operation of the valve assembly 10. In order to reduce the weight of the overall valve assembly 10, the sleeve 12 and the spool 20 are formed of a non-steel material. The relatively softer and lighter material may be any suitable material that depends on the particular application. In one embodiment, the material comprises aluminum.

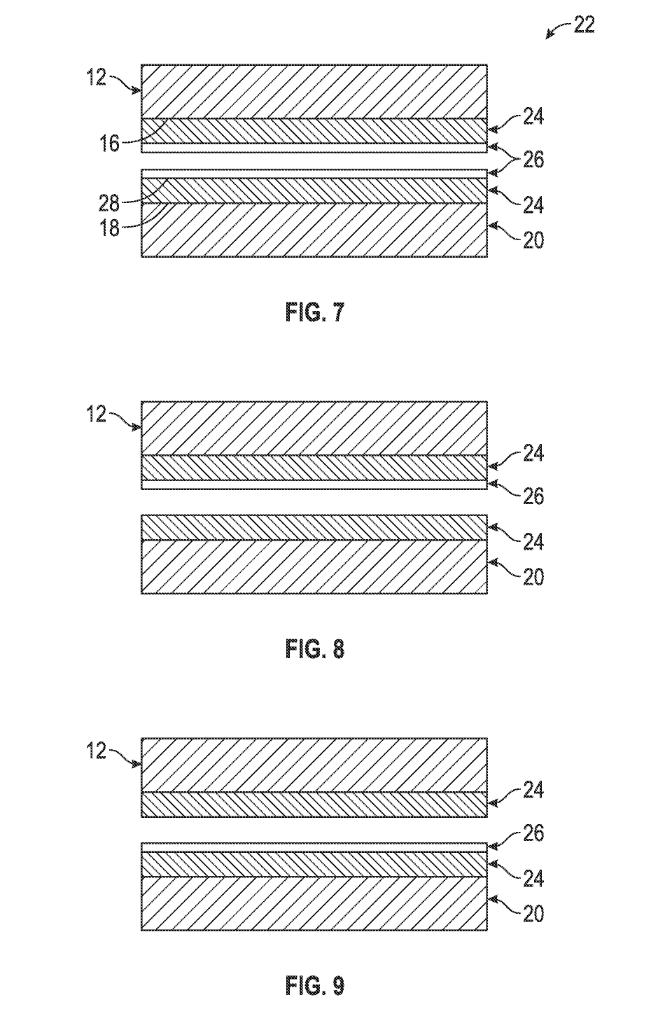

Referring to FIGS. 7-9, the sleeve inner surface 16 and the spool outer surface 18 are substrates for a coating arrangement 22 to be formed along the respective surfaces. The coating arrangement 22 may be arranged in numerous embodiments, as illustrated and described below.

The coating arrangement 22 includes a hardened surface 24 formed on the sleeve inner surface 16 and the spool outer surface 18. The hardened surface 24 may be formed by application of a coating or by any surface modification (e.g., machining) technique that increases the hardness of the sleeve inner surface 16 and the spool outer surface 18. In an embodiment having a coating, such as a base coating, as the hardened surface 24, a thermal spray coating or the like may be applied, for example. Machined surfaces may be formed in any suitable manner, such as plating, for example. Regardless of the particular manner in which the hardened surface 24 is formed, the hardened surface 24 is applied and/or machine finished to a surface roughness of less than or equal to about 0.000004 inches. In an exemplary embodiment, the hardened surface 24 comprises a hardened surface thickness of about 0.001 inches to about 0.010 inches.

Upon completion of the formation of the hardened surface 24, a coating 26 is applied along an outer surface 28 of the hardened surface 24 to effectively form a second coating layer of the coating arrangement 22. In one embodiment (FIG. 7), the coating 26 is applied to the hardened surface 24 of both the sleeve inner surface 16 and the spool outer surface 18. In alternative embodiments (FIGS. 8 and 9), the coating 26 is applied to the hardened surface 24 of only one of the surfaces. In other words, the hardened surface 24 of either the sleeve inner surface 16 and the spool outer surface 18 is coated with the coating 26, while the other is left uncoated.

The coating 26 comprises a diamond-like carbon (DLC) coating that may be applied to the hardened surface 24 in a number of ways. The DLC coating may be applied by physical vapor deposition and the precise thickness of the DLC coating may vary depending on the application. In one embodiment, the coating 26 comprises a coating thickness of about 0.000050 inches to about 0.000250 inches.

The thickness range of the hardened surface 24 specified above provides a substrate that is well-suited for bonding of the coating 26. In contrast to direct application of the coating 26 to a soft material, which is prone to flaking and general removal, the coating 26 of the above-described coating arrangement 22 is configured to adhere to the hardened surface in a durable manner.

Advantageously, the DLC coating provides a hard, low-friction surface to resist wear, and is particularly appropriate for the sliding applications described above, such as the types of the valve assembly 10 illustrated and described herein. This is based on the tightly controlled conformal contact surfaces and low contact loads.

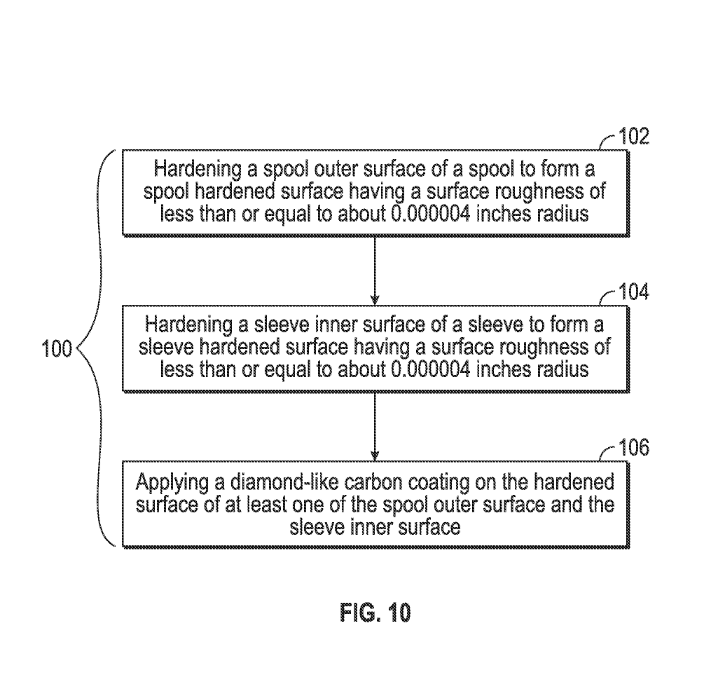

A method of coating components of a valve assembly 100 is also provided, as illustrated in FIG. 10 and with reference to FIGS. 1-9. The valve assembly 10 and the coating arrangement 22 have been previously described and specific structural components need not be described in further detail. The method of coating components of a valve assembly 100 includes hardening 102 the spool outer surface 18 of the spool 20 to a spool hardened surface having a surface roughness of about 0.000004 inches. Additionally, the sleeve inner surface 16 of the sleeve 12 is hardened 104 to a sleeve hardened surface having a surface roughness of about 0.000004 inches. A diamond-like carbon coating is applied 106 on the hardened surface of at least one of the spool outer surface 18 and the sleeve inner surface 16.

The numerous techniques that may be employed to form the hardened surfaces of the sleeve inner surface 16 and the spool outer surface 18 are described in detail above. Additionally, as noted above, the coating 26 may be applied by a physical vapor deposition process. Both the hardened surfaces and the coating 26 are formed to the dimensions described in detail above and the coating 26 may be applied to one or both of the hardened surfaces.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A coated valve assembly comprising:
a sleeve having a sleeve outer surface and a sleeve inner surface;
a spool having a spool outer surface;
a hardened surface formed on the sleeve inner surface and the spool outer surface; and
a coating disposed on the hardened surface of at least one of the spool outer surface and the sleeve inner surface, the second coating comprising a diamond-like carbon coating.

2. The coated valve assembly of claim 1, wherein at least one of the sleeve and the spool are formed of a material comprising aluminum.

3. The coated valve assembly of claim 1, wherein the coating is only disposed on the sleeve inner surface.

4. The coated valve assembly of claim 1, wherein the coating is only disposed on the spool outer surface.

5. The coated valve assembly of claim 1, wherein the coating is disposed on both the sleeve inner surface and the spool outer surface.

6. The coated valve assembly of claim 1, wherein the hardened surface comprises a hardened surface thickness of about 0.001 inches to about 0.010 inches.

7. The coated valve assembly of claim 1, wherein the hardened surface comprises a surface roughness of less than or equal to about 0.000004 inches.

8. The coated valve assembly of claim 1, wherein the coating comprises a coating thickness of about 0.000050 inches to about 0.000250 inches.

9. The coated valve assembly of claim 1, wherein the hardened surface comprises a base coating.

10. The coated valve assembly of claim 9, wherein the base coating comprises a thermal spray coating.

11. The coated valve assembly of claim 1, wherein the hardened surface comprises a machined surface.

12. The coated valve assembly of claim 1, wherein the coated valve assembly comprises a fuel control metering valve.

13. The coated valve assembly of claim 1, wherein the coated valve assembly comprises a pressure regulating valve.

14. A method of coating components of a valve assembly, the method comprising:
hardening a spool outer surface of a spool to form a spool hardened surface having a surface roughness of less than or equal to about 0.000004 inches ;
hardening a sleeve inner surface of a sleeve to form a sleeve hardened surface having a surface roughness of less than or equal to about 0.000004 inches ; and
applying a diamond-like carbon coating on the hardened surface of at least one of the spool outer surface and the sleeve inner surface.

15. The method of claim 14, wherein the diamond-like carbon coating is applied by a physical vapor deposition process.

16. The method of claim 14, wherein applying the diamond-like carbon coating comprises applying a coating thickness of about 0.000050 inches to about 0.000250 inches.

17. The method of claim 14, wherein hardening the spool outer surface and the sleeve inner surface comprises applying a base coating.

18. The method of claim 14, wherein hardening the spool outer surface and the sleeve inner surface comprises machining the spool outer surface and the sleeve inner surface.

19. The method of claim 14, wherein the diamond-like carbon coating is applied to both the sleeve inner surface and the spool outer surface.

20. A coating arrangement for sliding actuator assembly comprising:
a first component having an outer surface and an inner surface;
a second component having an outer surface;
a hardened surface formed on the inner surface of the first component and the outer surface of the second component; and
a coating disposed on the hardened surface of at least one of the outer surface of the second component and the inner surface of the first component, the second coating comprising a diamond-like carbon coating.
